(19) United States
(12) Patent Application Publication
(10) Pub. No.: US 2024/0397836 A1
(43) Pub. Date: Nov. 28, 2024

(54) MEMORY DEVICE AND FORMATION METHOD THEREOF

(71) Applicants: Taiwan Semiconductor Manufacturing Company, Ltd., Hsinchu (TW); NATIONAL TAIWAN UNIVERSITY, TAIPEI (TW)

(72) Inventors: Chen-Hsiang LING, Kaohsiung City (TW); Miin-Jang CHEN, Taipei City (TW)

(73) Assignees: Taiwan Semiconductor Manufacturing Company, Ltd., Hsinchu (TW); NATIONAL TAIWAN UNIVERSITY, TAIPEI (TW)

(21) Appl. No.: 18/473,580

(22) Filed: Sep. 25, 2023

Related U.S. Application Data
(60) Provisional application No. 63/468,600, filed on May 24, 2023.

(51) Int. Cl. H10N 70/00; H10B 63/00

(52) U.S. Cl. CPC H10N 70/023; H10B 63/80; H10N 70/841; H10N 70/883

(57) ABSTRACT

A method includes following steps. A bottom electrode layer is formed over a substrate. A first deposition sequence is performed over the bottom electrode layer. The first deposition sequence comprises pulsing a first precursor over the bottom electrode layer such that the first precursor comprises a first plurality of precursor molecules adsorbing on the bottom electrode layer, performing a first purge after pulsing the first precursor, performing a first plasma treating step using a first treatment gas, wherein the first treatment gas reacts with the first plurality of precursor molecules to form a first monolayer of a film, the film has an Al—N bond with a first intensity, pulsing the first treatment gas, and after pulsing the first treatment gas, performing a second plasma treating step using a second treatment gas such that the film has an Al—N bond with a second intensity.

### RELATED APPLICATION

This application claims priority to U.S. Provisional Patent Application Ser. No. 63/468,600, filed May 24, 2023, all of which are herein incorporated by reference in their entireties.

### BACKGROUND

The semiconductor integrated circuit (IC) industry has experienced rapid growth. In the course of IC evolution, functional density (i.e., the number of interconnected devices per chip area) has increased while geometry size (i.e., the smallest component (or line) that can be created using a fabrication process) has decreased. This scaling down process increases production efficiency and lowers associated costs.

Such scaling down has also increased the complexity of processing and manufacturing ICs and, for these advances to be realized, similar developments in IC processing and manufacturing are desired. For example, a three dimensional transistor, such as a fin-like field-effect transistor (FinFET), has been introduced to replace a planar transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2 and 3 are perspective views of a method for manufacturing a memory device using a fabrication apparatus at various stages in accordance with some embodiments of the present disclosure.

FIG. 4 shows a start of a process to form the metal nitride layer over the bottom electrode layer by placing the memory device into a fabrication apparatus according to some embodiments of the present disclosure.

FIG. 5 is a cross-sectional view of a method for forming monolayers of the metal nitride layer using the fabrication apparatus at various stages in accordance with some embodiments of the present disclosure.

FIG. 6A is a cross-sectional view of monolayers of the metal nitride layer in accordance with some embodiments of the present disclosure.

FIGS. 6B, 6C and 6D are schematic cross-sectional views of monolayers of metal nitride layer in accordance to a comparative example, a comparative example, and an example of the present disclosure.

FIGS. 7A, 7B and 7C are X-ray photoelectron spectroscopy (XPS) spectra illustrating aspects of the metal nitride layers in accordance to a comparative example, a comparative example, and an example in accordance with some embodiments.

FIG. 7D is a table showing intensities of Al—N bond, Al—Al bond, and Al—O bond of the metal nitride layers of the comparative example, the comparative example, and the example of FIGS. 7A, 7B and 7C.

FIG. 8 is an X-ray reflectometry (XRR) spectra of the metal nitride layers of the comparative example, the comparative example, and the example of the present disclosure.

FIG. 9 is a perspective view of a method for manufacturing a memory device using a fabrication apparatus at various stages in accordance with some embodiments of the present disclosure.

FIGS. 10-12 are cross-sectional views of a method for manufacturing the memory device using a fabrication apparatus at various stages in accordance with some embodiments of the present disclosure.

FIG. 13A is a perspective view of a method for manufacturing a memory device using a fabrication apparatus at various stages in accordance with some embodiments of the present disclosure.

FIG. 13B is a cross-sectional view cutting along line B-B′ of FIG. 13A.

FIGS. 14A-14C are diagrams showing current versus voltage in accordance with the example of the present disclosure and the first and comparative examples.

FIG. 15A is a diagram showing cumulative probability (%) versus voltage in accordance with the example and the comparative example.

FIG. 15B is a diagram showing cumulative probability (%) versus resistance in accordance with the example and the comparative example.

FIGS. 16A-16C are diagrams showing current versus voltage in accordance with a comparative example, an example of the present disclosure and an example of the present disclosure.

FIG. 17A is a diagram showing cumulative probability (%) versus voltage in accordance with the example and the comparative example.

FIG. 17B is a diagram showing cumulative probability (%) versus resistance in accordance with the example and the comparative example.

FIGS. 18A-18C are diagrams of resistance versus cycles in accordance with the comparative example, the example and the example.

FIGS. 19A-19C are diagrams of resistance versus time in accordance with the comparative example, the example and the example.

FIGS. 20A-20D are cross-sectional views of a stack of the Pt bottom electrode layer, the metal nitride layer and the TIN top electrode layer in accordance with the comparative example.

FIGS. 21A-21D are cross-sectional views of a stack of the Pt bottom electrode layer, the metal nitride layer and the TIN top electrode layer in accordance with the example.

FIGS. 22A-22C are cross-sectional views of a stack of the Pt bottom electrode layer, the metal nitride layer and the TIN top electrode layer in accordance with the comparative example.

FIGS. 23A-23C are cross-sectional views of a stack of the Pt bottom electrode layer, the first metal nitride layer, the second metal nitride layer and the TIN top electrode layer in accordance with the example.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated.

Emerging big data applications give rise to an urgent demand for nonvoltaile memory devices with high performance. Among candidates of nonvoltaile memory devices, resistive random access memory (RRAM) has several advantages. A variety of metal oxides have been used as a resistive switching layer in RRAM devices. However, local heating effect in the metal oxides results in challenges including non-uniformity of resistive switching characteristics in the RRAM.

Embodiments of the present disclosure relate to a resistive random access memory (RRAM) device including a metal nitride layer, such as an AlN layer. The AlN layer can suppress a local heating effect in the vicinity of conductive filaments, thereby improving controllability of conductive filaments in the RRAM device. By forming the AlN layer by a deposition method including atomic layer annealing (ALA), the RRAM device can have an improved performance.

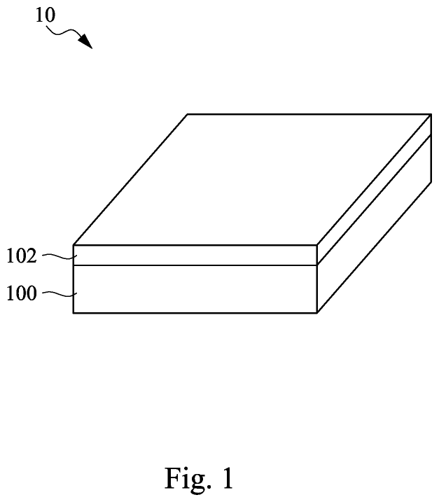

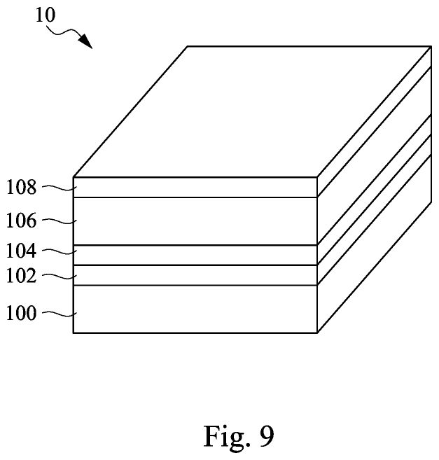

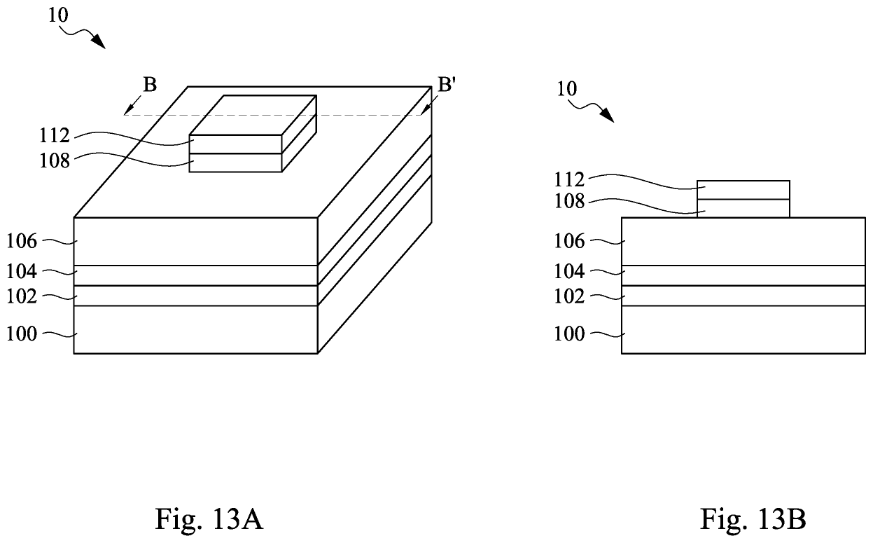

FIGS. 1, 2, 3, 9 and 13A are perspective views of a method for manufacturing a memory device 10 using a fabrication apparatus at various stages in accordance with some embodiments of the present disclosure. In some embodiments, the memory device 10 is a resistive random access memory (RRAM) device. FIGS. 10-12 are cross-sectional views of a method for manufacturing the memory device 10 using a fabrication apparatus at various stages in accordance with some embodiments of the present disclosure. FIG. 13B is a cross-sectional view cutting along line B-B′ of FIG. 13A.

Reference is made to FIG. 1. In some embodiments, a first conductive layer 102 is formed on a substrate 100. In certain embodiments, the first conductive layer 102 is a TiN layer formed by sputtering. In some other embodiments, the first conductive layer 102 may be formed by PVD, CVD, or other suitable methods.

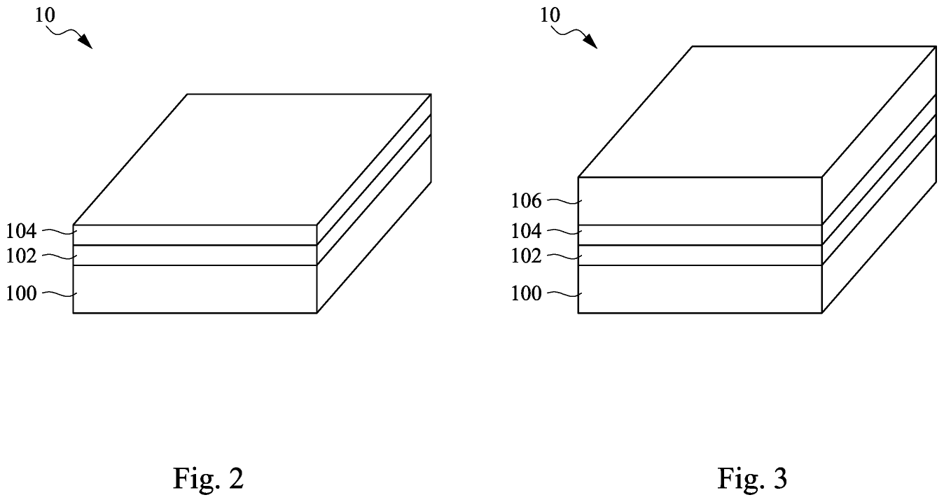

Reference is made to FIG. 2. In some embodiments, a bottom electrode layer 104 is formed on the first conductive layer 102. In certain embodiments, the bottom electrode layer 104 includes metal, such as Pt, and is formed by sputtering. In some other embodiments, the bottom electrode layer 104 may be formed by PVD, CVD, or other suitable methods.

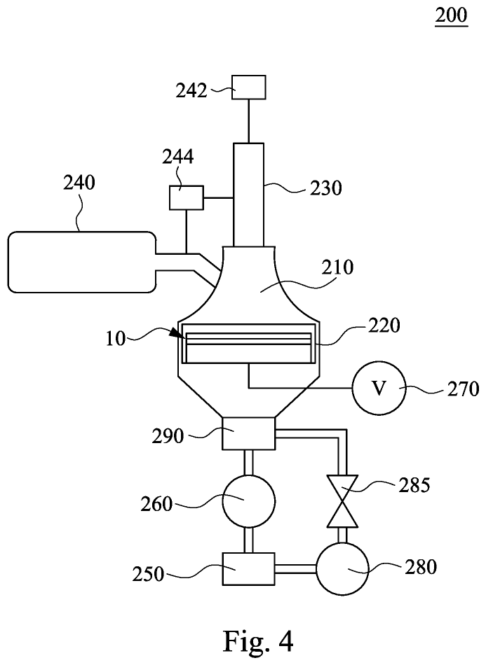

Reference is made to FIG. 3. In some embodiments, a metal nitride layer 106 is formed on the bottom electrode layer 104. In some embodiments, the metal nitride layer 106 is an aluminum-containing layer, such as an AlN layer formed by using atomic layer deposition (ALD).

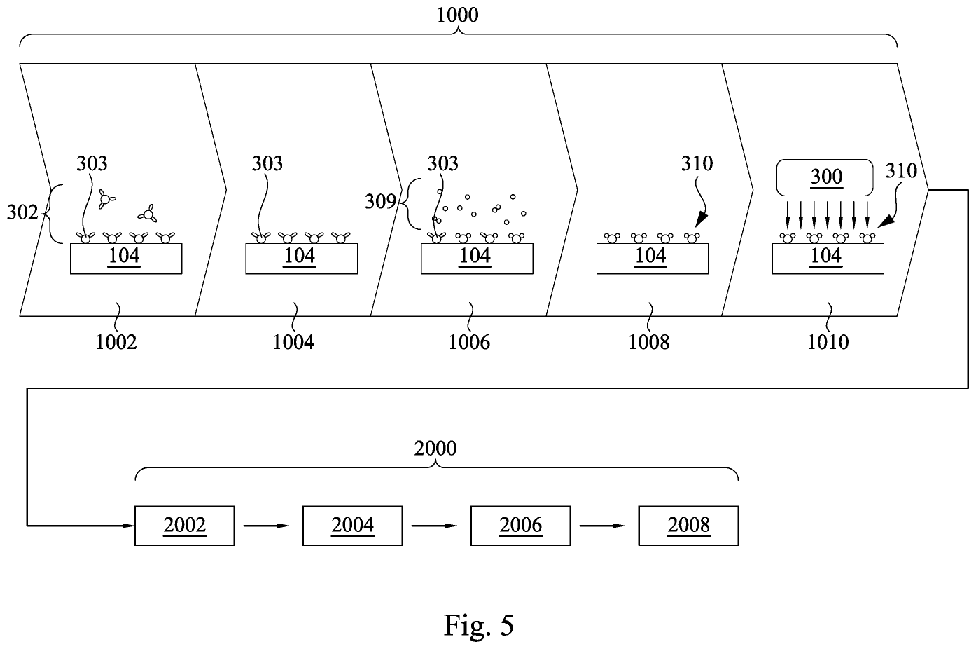

FIG. 4 shows a start of a process to form the metal nitride layer 106 over the bottom electrode layer 104 by placing the memory device 10 into a fabrication apparatus 200 according to some embodiments of the present disclosure. Reference is made to FIGS. 3 and 4. In an embodiment, the fabrication apparatus 200 includes a chamber 210, a chuck 220, a plasma source 230, a precursor delivery system 240, and a treatment gas delivery system 242. The chuck 220 is in the chamber 210, and the plasma source 230 and the precursor delivery system 240 are connected to the chamber 210. The fabrication apparatus 200 receives precursor gases from the precursor delivery system 240. A purge gas delivery system (not shown) may be connected to the chamber 210 to provide a purge gas to the chamber 210.

The plasma source 230 may be a remote plasma system which is separated from the chamber 210. A treatment gas is delivered from the treatment gas delivery system 242 into an internal volume of the plasma source 230 to flow from the plasma source 230 towards the substrate 100. A remote plasma may be generated in the plasma source 230 to produce radicals of the treatment gas. The remote plasma may also produce ions and other charged species of the treatment gas. For example, coils (not shown), which may be electrical communication with a radio frequency (RF) power source or a microwave plasma source, surround walls of the plasma source 230 and generate a remote plasma in the plasma source 230. The ions or charged species of the treatment gas may move to a surface of the bottom electrode layer 104 to react or contact the bottom electrode layer 104. The ions or charged species may freely drift toward the surface of the bottom electrode layer over the substrate 100 when an oppositely charged bias is provided on the chuck 220.

The fabrication apparatus 200 receives a precursor from the precursor delivery system 240. In other embodiments, more precursor delivery systems may be used. In some embodiments, the fabrication apparatus 200 further includes a turbo pump 250 and a pressure controller 260 (e.g., automatic pressure controller (APC)). The turbo pump 250 is connected to the chamber 210 through the pressure controller 260. In some embodiments, when the memory device 10 is positioned in the chamber 210, a vacuum is applied to the chamber 210 by the turbo pump 250 to remove oxygen and moisture. The pressure controller 260 is configured to control the pressure inside the chamber 210. In some embodiments, when the memory device 10 is positioned in the chamber 210. the temperature is raised to an acceptable level that is suitable for the deposition to form the film on the memory device 10. The bias source 270 is configured to apply a bias to the chuck 220 and thus to the substrate 100 positioned thereon. In some embodiments, the bias source 270 is configured to apply a direct current (DC) bias, an alternating current (AC) bias, or a DC/AC superposed bias, to the chuck 220. In some embodiments, the bias source 270 is configured to apply positive or negative DC bias to the chuck 220 to accelerate or decelerate a deposition rate of the deposition process. In some embodiments, the bias is a radio frequency (RF) bias, and the frequency range thereof is in a range of about 3 kHz to about 300 GHz.

In some embodiments, the fabrication apparatus 200 in FIG. 4 further includes a rotary pump 280 and a valve (e.g., stop valve) 285. The rotary pump 280 is connected to the chamber 210 via the valve 285, and the rotary pump 280 is configured to pump out the purging gases and the excess precursors in the chamber 210 when the pressure controller 260 is turned off. In some other embodiments, the turbo pump 250 may pump out the purging gases and the excess precursors in the chamber 210 when the pressure controller 260 is turned on. In some embodiments, the fabrication apparatus 200 in FIG. 4 further includes a filter (e.g., trap filter) 290 connected to the chamber 210, the valve 285, and the pressure controller 260. The filter 290 is configured to trap the gases (e.g., the purging gases and/or precursors) and prevent the gases reflected toward the chamber 210.

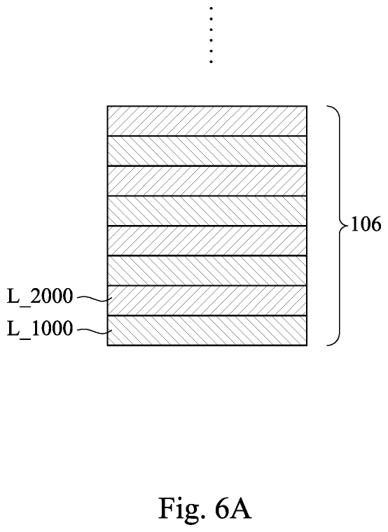

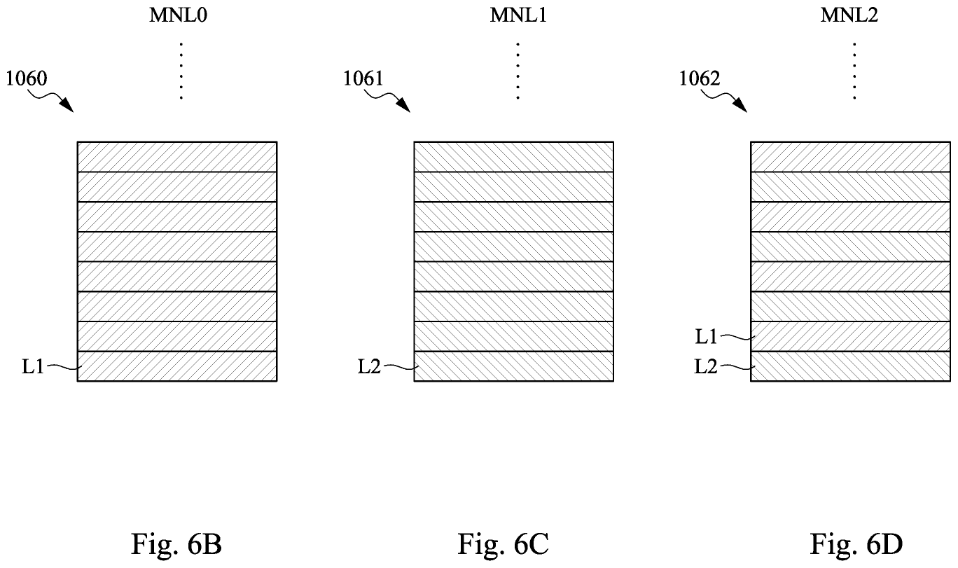

Subsequently, the metal nitride layer 106 may be formed on the bottom electrode layer 104 using an atomic layer deposition (ALD) process including a number of repeated deposition cycles by the fabrication apparatus 200. FIG. 5 is a cross-sectional view of a method for forming monolayers of the metal nitride layer 106 using the fabrication apparatus 200 at various stages in accordance with some embodiments of the present disclosure. FIG. 6A is a cross-sectional view of monolayers of the metal nitride layer 106 in accordance with some embodiments of the present disclosure. Reference is made to FIGS. 5 and 6A. In some embodiments, the number of repeated deposition cycles are performed at a temperature in a range from about 200° C. to about 400° C., such as about 300° C. In some embodiments, the ALD process may be a plasma-enhanced ALD process. In some embodiments, a deposition cycle of the metal nitride layer 106 may include a first deposition sequence 1000 followed by a second deposition sequence 2000. The first deposition sequence 1000 includes a first precursor pulsing step 1002, a purging step 1004, a plasma treating step 1006, a purging step 1008 and an atomic layer annealing (ALA) step 1010. The second deposition sequence 2000 may include a first precursor pulsing step 2002, a purging step 2004, a plasma treating step 2006 and a purging step 2008, which will be described in greater details below.

Reference is made to FIGS. 4, 5 and 6A.In FIG. 5, for the first deposition sequence 1000, the first precursor pulsing step 1002, the purging step 1004, the plasma treating step 1006, the purging step 1008 and the atomic layer annealing (ALA) step 1010 are illustrated as blocks. In the first precursor pulsing step 1002, a first precursor (e.g., Trimethylaluminum (TMA), Triethylaluminium (TEA), Tetrakis(dimethylamido) aluminum (TDMAA)) 302 is pulsed into the chamber 210 of the fabrication apparatus 200 from the precursor delivery system 240. The first precursor 302 is a metal-containing precursor, such as aluminum-containing precursor. The first precursor 302 has precursor molecules. For example, the first precursor 302 includes a first plurality of precursor molecules 303 adsorbs onto a top surface of the bottom electrode layer 104. In some embodiments, a pulse of the first precursor is injected into the chamber 210 for a period of time, for example, in a range from about 0.01 s to about 0.5 s, such as about 0.07 s.

In the purging step 1004, an excess portion of the first precursor 302 is purged from over the bottom electrode layer 104 with a purge gas. For example, a control unit 244 may disconnect the precursor delivery system 240 and to connect a purge gas delivery system (not shown) to deliver a purge gas to the chamber 210. In some embodiments, the purge gas may include argon (Ar), nitrogen (N₂), xeon (Xe), or other non-reactive gas. In some embodiments, the control unit 244 may also initiate the rotary pump 280 to aid in the removal of the excess portion of the first precursor 302. In some embodiments, the first precursor may be purged for a time period in a range from about 5 s to about 30 s, such as about 15 s.

In the plasma treating step 1006, a treatment gas is delivered from the treatment gas delivery system 242 into an internal volume of the plasma source 230 to flow from the plasma source 230 towards the bottom electrode layer 104. In some embodiments, gases used in the plasma treating step 1006 include nitrogen gas, hydrogen gas, or a combination thereof. A remote plasma 300 may be generated in the plasma source 230 to produce radicals of the treatment gas. The remote plasma 300 may also produce ions and other charged species of the treatment gas. In some embodiments, the plasma energy for the plasma treating step 1006 is in a range from about 200 W to about 400 W, such as about 300 W. In some embodiments, the plasma treating step 1006 is performed for a period of time, for example, in a range from about 30 s to about 50 s, such as about 40 s. The treatment gas has a plurality of molecules 309 reacting with the plurality of precursor molecules 303 of the first precursor 302 adsorbed on the bottom electrode layer 104, forming a first monolayer 310 of metal nitride, such as AlN, as shown in the purging step 1008.

In the ALA step 1010, an excess portion of the treatments gas is purged from over the bottom electrode layer 104 with a purge gas. For example, a control unit 244 may disconnect the precursor delivery system 240 and to connect a purge gas delivery system (not shown) to deliver a purge gas to the chamber 210. In some embodiments, the purge gas may include argon (Ar), nitrogen (N₂), xeon (Xe), or other non-reactive gas. In some embodiments, the control unit 244 may also initiate the rotary pump 280 to aid in the removal of the excess portion of the first precursor 302. In some embodiments, the treatment gas may be purged for a time period in a range from about 5 s to about 30 s, such as about 10 s.

Next, a treatment gas is delivered from the treatment gas delivery system 242 into an internal volume of the plasma source 230 to flow from the plasma source 230 towards the bottom electrode layer 104. In some embodiments, the treatment gas used in the ALA step 1010 has a composition different from a composition of the treatment gas used in the plasma treating step 1006. In some embodiments, the treatment gas used in the ALA step 1010 includes inert gas, such as He gas, Ar gas, or a combination thereof. That is, the treatment gas used in the ALA step 101 is a mixture of He and Ar. In some embodiments, a flow rate of the He gas is in a range from about 50 sccm to about 100 sccm, such as about 70 sccm, and a flow rate of the Ar gas is in a range from about 100 sccm to about 150 sccm, such as about 130 sccm. A remote plasma 300 may be generated in the plasma source 230 to produce radicals of the treatment gas. The remote plasma 300 may also produce ions and other charged species of the treatment gas. In some embodiments, the plasma energy for the ALA step 1010 is in a range from about 200 W to about 400 W, such as about 300 W. In some embodiments, the ALA step 1010 is performed for a period of time, for example, in a range from about 10 s to about 50 s, such as about 20 s. By incorporating the ALA step 1010 in the first deposition sequence 1000 after the purging step 1008, the energy transfers from the plasma species in the ALA step 1010 can enhance chemical reaction and adatom migration at a film surface of first monolayer 310 of the metal nitride layer, such as AlN, which is favorable for an increase in the film density and a decrease in the nitrogen vacancies. For example, the first monolayer 310 has an Al—N bond with a first intensity after the purging step 1008. the first monolayer 310 has an Al—N bond with a second intensity after the ALA step 1010, and the first intensity is different from the second intensity. In certain embodiments, the first intensity is less than the second intensity.

After the first deposition sequence 1000 is performed, a second deposition sequence 2000 is performed. The second deposition sequence 2000 is similar to the first deposition sequence 1000, except for in the second deposition sequence 2000, the ALA step is omitted. For example, the first precursor pulsing step 1002 is similar to the first precursor pulsing step 2002, the purging step 1004 is similar to the purging step 2004, the plasma treating step 1006 is similar to the plasma treating step 2006, and the purging step 1008 is similar to the purging step 2008. The treatment gas in the plasma treating step 2006 has a plurality of molecules reacting with the plurality of precursor molecules of the first precursor, forming a second monolayer of the metal nitride, such as AlN.

By using the deposition cycle formed by the first deposition sequence 1000 and the second deposition sequence 2000, the as-deposited metal nitride layer 106 is formed by alternating stacked first monolayers L_1000 of metal nitride (e.g., AlN monolayers) and second monolayers L_2000 of metal nitride (e.g., AlN monolayers). In other words, the ALA step 1010 is performed in every two 2 ALD cycles. In some embodiments, no delay time is between the first deposition sequence 1000 and the second deposition sequence 2000. In other words, no delay time is between the ALA step 1010 and the first precursor pulsing step 1002 (e.g., the TMA pulse) in a subsequent ALD cycle. As discussed previously, the ALA step 1010 can enhance the chemical reaction and the adatom migration at a film surface of the first monolayers L_1000 of the metal nitride layer 106. Therefore, the metal nitride layer 106 can have an increased film density and a decreased nitrogen vacancies. In other words, the first monolayers L_1000 have a material same as a material of the second monolayers L_2000, and the first monolayers L_1000 have a density different from a density of the second monolayers L_2000.

In some other embodiments, the ratio of the first deposition sequence 1000 and the second deposition sequence 2000 can be modified to control a spatial distribution or a content of vacancies and defects of the metal nitride layer 106. By modulating a frequency of the ALA step 1010 incorporated in the ALD cycles, a film quality can be tailored with a monolayer accuracy, which is favorable for RRAM device application, and a resistive switching behavior of the RRAM device can be affected in various aspects. In some embodiments, a number of the first deposition sequence 1000 is substantially the same as a number of the second deposition sequence 2000. That is, a number of the first monolayers L_1000 and the number of the second monolayers L_2000 are substantially the same. In particular, positions of the ALA step 1010 in the deposition of the metal nitride layer 106 can be modulated such that a position of the rupture and reconstruction of conductive filaments in the metal nitride layer 106 can be controlled, which will be discussed in greater detail later, and a resistive switching behavior of the RRAM can be affected in various aspects. The ALA step 1010 in every 2 ALD cycles (i.e., the first deposition sequence 1000 and the second deposition sequence 2000) can contribute to a decrease in operating voltage and uniformity improvement of the resistive switching characteristics.

The densification of the metal nitride layer 106 can be increased, and the nitrogen vacancy content in the metal nitride layer 106 can be decreased with the frequency of the ALA step 1010 applied in the ALD cycles of the metal nitride layer 106. FIGS. 6B, 6C and 6D are schematic cross-sectional views of monolayers of metal nitride layer 1060, 1061, 1062 in accordance to a comparative example MNL0, a comparative example MNL1, and an example MNL2 of the present disclosure.

### Comparative Example MNL0

The metal nitride layer 1060 are formed by monolayers L1 without any ALA step (see FIG. 5) using ALD process.

### Comparative Example MNL1

The metal nitride layer 1061 are formed by monolayers L2 in which each of the monolayers L2 is formed by incorporating an ALA step (see FIG. 5) in each ALD cycle using ALD process.

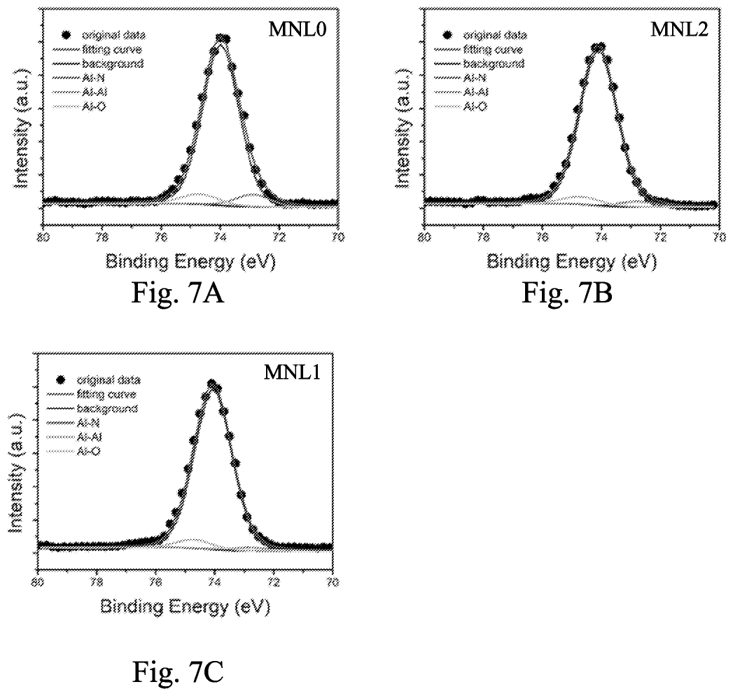

FIGS. 7A, 7B and 7C are X-ray photoelectron spectroscopy (XPS) spectra illustrating aspects of the metal nitride layers in accordance to a comparative example MNL0, a comparative example MNL1, and an example MNL2 in accordance with some embodiments. FIG. 7D is a table showing intensities of Al—N bond, Al—Al bond, and Al—O bond of the metal nitride layers of the comparative example MNL0, the comparative example MNL2, and the example MNL1 of FIGS. 7A, 7B and 7C. The example MNL2 of the present disclosure shows an Al—N bond intensity greater than an Al—N bond intensity of the comparative example MNL0. The example MNL2 shows an Al—Al bond intensity less than an Al—Al bond intensity of the comparative example MNL0.

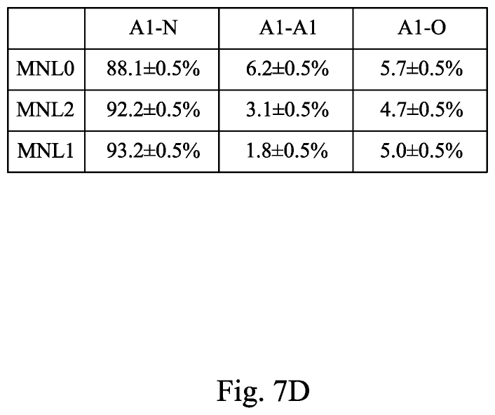

FIG. 8 is an X-ray reflectometry (XRR) spectra of the metal nitride layers of the comparative example MNL0, the comparative example MNL2, and the example MNL1 of the present disclosure. Reference is made to FIGS. 6B-6C and 8. The metal nitride layer 1062 of the example MNL2 shows a critical angle between the normalized intensities of the metal nitride layers 1060, 1061 of the comparative examples MNL0 and MNL1, respectively, which indicates that the film density of metal nitride layer 1062 is between the metal nitride layers 1060, 1061 of the comparative examples MNL0 and MNL1, and the metal nitride layer 1062 of the example MNL2 has nitrogen vacancies between nitrogen vacancies of the metal nitride layers 1060, 1061 of the comparative examples MNL0 and MNL1.

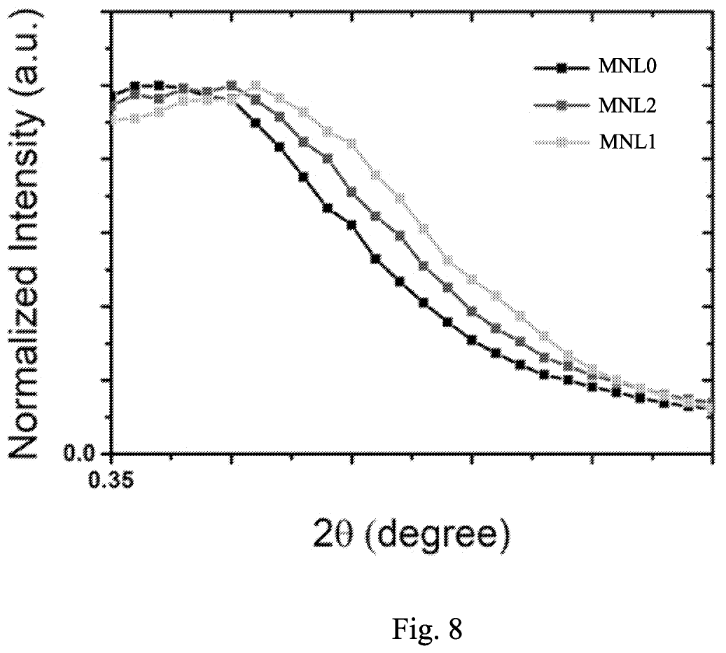

Reference is made to FIG. 9. In some embodiments, a top electrode layer 108 is formed on the metal nitride layer 106. In some embodiments, the top electrode layer 108 is in contact with the metal nitride layer 106. In certain embodiments, the top electrode layer 108 includes a Ti-containing layer, such as TiN or other suitable material, and is formed by sputtering. In some other embodiments, the top electrode layer may be formed by PVD, CVD, or other suitable methods.

Reference is made to FIG. 10. A mask layer 110 is formed over the top electrode layer 108 and then patterned to expose the top electrode layer 108. In some embodiments, the mask layer 110 may be a photoresist material formed using a spin-on coating process, followed by patterning the photoresist material using suitable lithography techniques. For example, photoresist material is irradiated (exposed) and developed to remove portions of the photoresist material. In greater detail, a photomask (not shown) may be placed over the photoresist material, which may then be exposed to a radiation beam provided by a radiation source such as ultraviolet (UV) source, deep UV (DUV) source, extreme UV (EUV) source, and X-ray source. For example, the radiation source may be a mercury lamp having a wavelength of about 436 nm (G-line) or about 365 nm (I-line); a Krypton Fluoride (KrF) excimer laser with wavelength of about 248 nm; an Argon Fluoride (ArF) excimer laser with a wavelength of about 193 nm; a Fluoride (F₂) excimer laser with a wavelength of about 157 nm; or other light sources having an appropriate wavelength (e.g., below approximately 100 nm). In another example, the light source is an EUV source having a wavelength of about 13.5 nm or less.

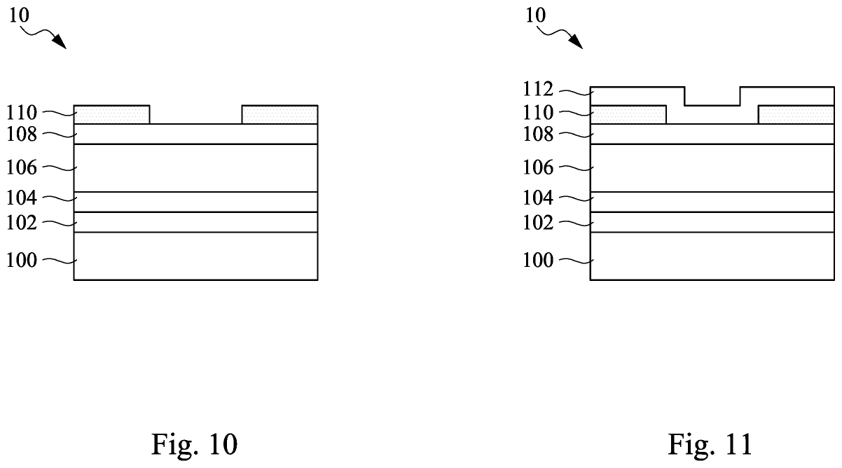

Reference is made to FIG. 11. A second conductive layer 112 is formed on the mask layer 110 and the top electrode layer 108 such as using ALD, CVD, LPCVD, PVD, plating, evaporation, ion beam, energy beam, the like, or a combination thereof. In certain embodiments, the second conductive layer 112 is metal, such as Pt, and may be formed by formed by suitable deposition method such as sputtering.

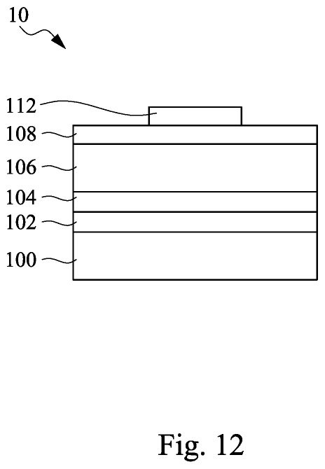

The mask layer 110 is removed by using, for example, a lift-off process. Lifting off the mask layer 110 also removes an overlying portion of the second conductive layer 112, thus leaving other portions of the second conductive layer 112 on the top electrode layer. The resulting structure is shown in FIG. 12.

Reference is made to FIGS. 13A and 13B. In some embodiments, the top electrode layer 108 is etched by using the second conductive layer 112 as an etch mask. In some embodiments, the top electrode layer 108 is etched using a dry etch process, such as reactive ion etch (RIE). In some other embodiments, the top electrode layer 108 is etched using inductively coupled plasma (ICP), transformer coupled plasma (TCP), electron cyclotron resonance (ECR), or the like.

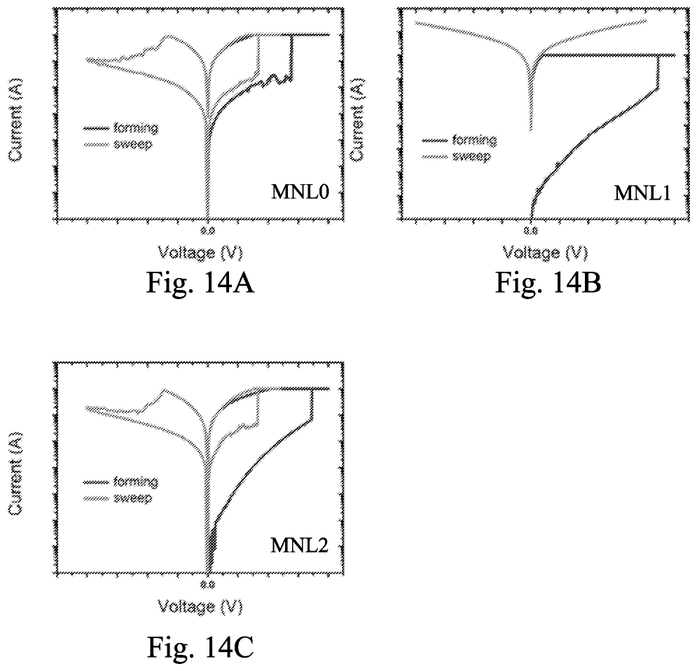

FIGS. 14A-14C are diagrams showing current versus voltage in accordance with the example MNL2 of the present disclosure and the comparative examples MNL0 and MNL1. Reference is made to FIGS. 6B-6C and FIGS. 14A-14C. For example, the metal nitride layers of the example MNL2 and the comparative examples MNL0 and MNL1 may be formed by about 30 to about 70 ALD cycles, such as about 50 ALD cycles. In “forming” operation process, a high voltage is applied to the RRAM device to generate a conductive path in a resistive material layer of the RRAM device. In FIG. 14A, for the comparative example MNL0, a stable resistive switching behavior is shown. In FIG. 14B, for the comparative example MNL1, hard breakdown occurs in the comparative example MNL1 during the forming process. In FIG. 14C, for the example MNL2 of the present disclosure, the hard breakdown is prevented during the forming process, and the resistive switching behavior thereof is maintained as well.

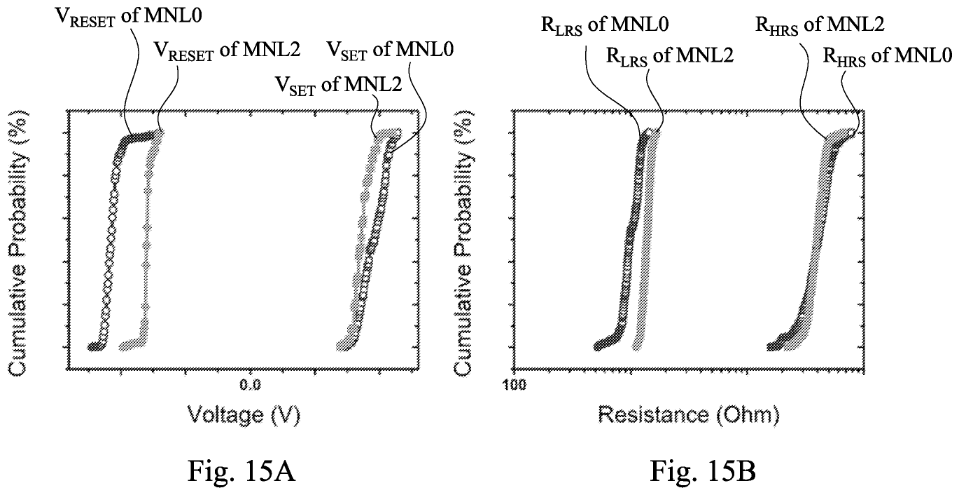

FIG. 15A is a diagram showing cumulative probability (%) versus voltage in accordance with the example MNL2 and the comparative example MNL0. FIG. 15B is a diagram showing cumulative probability (%) versus resistance in accordance with the example MNL2 and the comparative example MNL0. Reference is made to FIG. 15A. A V_{RESET} and V_{SET} of the example MNL2 are lower than a V_{RESET} and V_{SET} of the comparative example MNL0, respectively. A ratio of standard deviation to mean (σ/μ value) of V_{RESET} and V_{SET} of the example MNL2 has a narrower distribution and is smaller than the comparative example MNL0. For example, the σ/μ value of the V_{RESET} of the comparative example MNL0 is about 6.2%±0.5%, while the σ/μ value of the V_{RESET} of the example MNL2 is about 4.2%±0.5%. For example, the σ/μ value of the V_{SET} of the comparative example MNL0 is about 10.0%±0.5%, while the σ/μ value of the V_{SET} of the example MNL2 is about 7.4%±0.5%.

Reference is made to FIG. 15B. A resistance of low resistance state (LRS) and a resistance of high resistance state (HRS) of the example MNL2 has a narrower distribution and is smaller than a resistance of a low resistance state (LRS) and a resistance of a high resistance state (HRS) of the comparative example MNL0. For example, the σ/μ value of the resistance of LRS of the comparative example MNL0 is about 16.7%±0.5%, and the σ/μ value of the resistance of LRS of the example MNL2 is about 8.1%±0.5%. For example, the σ/μ value of the resistance of HRS of the comparative example MNL0 is about 27.1%±0.5%, and the σ/μ value of the resistance of HRS of the example MNL2 is about 16.8%±0.5%.

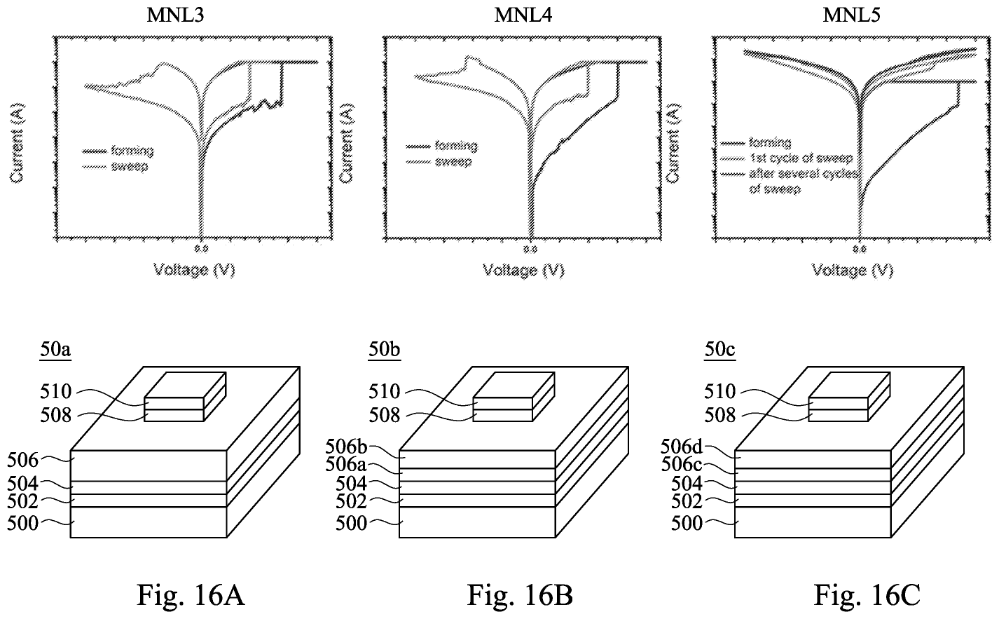

FIGS. 16A-16C are diagrams showing current versus voltage in accordance with a comparative example MNL3, an example MNL4 of the present disclosure and an example MNL5 of the present disclosure. Reference is made to FIGS. 16A-16C.

### Comparative Example 3

A memory device 50a includes a substrate 500, a first conductive layer 502, a Pt bottom electrode layer 504, a metal nitride layer 506, a TiN top electrode layer 508 and a second conductive layer 510 stacked in sequence.

### Example MNL4

A memory device 50b includes a substrate 500, a first conductive layer 502, a Pt bottom electrode layer 504, a first metal nitride layer 506a formed by ALD process without incorporating an ALA step, a second metal nitride layer 506b formed by ALD process by incorporating an ALA step, a TiN top electrode layer 508 and a second conductive layer 510 stacked in sequence.

### Example MNL5

A memory device 50c includes a substrate 500, a first conductive layer 502, a Pt bottom electrode layer 504, a first metal nitride layer 506c formed by ALD process by incorporating an ALA step, a second metal nitride layer 506d formed by ALD process without incorporating an ALA step, a TiN top electrode layer 508 and a second conductive layer 510 stacked in sequence.

In the memory device 50a of the comparative example MNL3, the metal nitride layer 506 is formed using ALD cycles of about 50±5. In the memory device 50b of the example MNL4, the first and second metal nitride layers 506a, 506b are formed using ALD cycles of about 50±5 in which the second metal nitride layer 506b, which is formed by ALD process by incorporating an ALA step, is deposited using ALD cycles of about 13±2. In the memory device 50c of the example MNL5, the first and second metal nitride layers 506c. 506d are formed using ALD cycles of about 50±5 in which the first metal nitride layer 506c, which is formed by ALD process by incorporating an ALA step, is deposited using ALD cycles of about 13±2.

Forming voltage of the metal nitride layer of the example MNL4 is greater than a forming voltage of the metal nitride layer of the comparative example MNL3 while a current of pristine of the example MNL4 is lower than a current of pristine of the comparative example MNL3. An HRS current of the example MNL4 is higher than an HRS current of the comparative example MNL3, while the LRS current of the example MNL4 is lower than a LRS current of the comparative example MNL3. The example MNL5 exhibits a hard breakdown after several operation cycles.

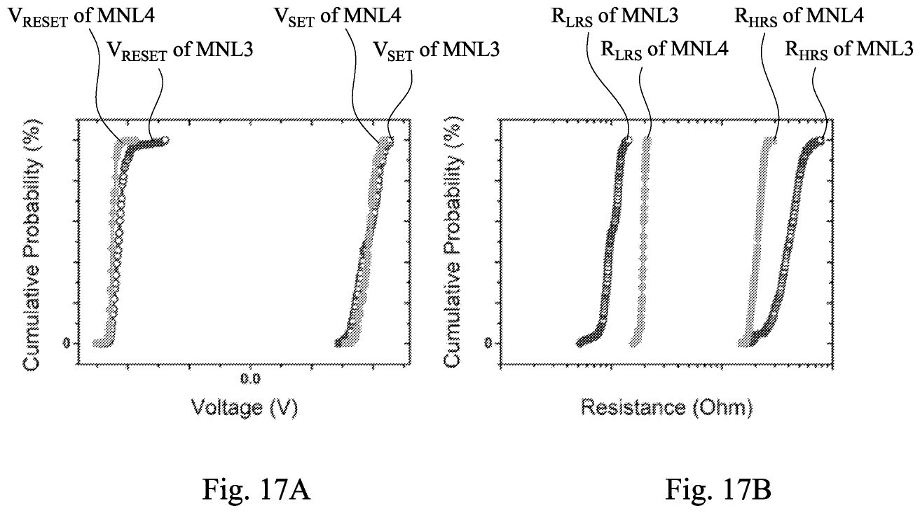

FIG. 17A is a diagram showing cumulative probability (%) versus voltage in accordance with the example MNL3 and the comparative example MNL4. FIG. 17B is a diagram showing cumulative probability (%) versus resistance in accordance with the example MNL3 and the comparative example MNL4. The example MNL4, which has the second metal nitride layer 506b formed by ALD process by incorporating an ALA step near the TiN top electrode layer 508 has an improved uniformity. An on/off ratio of the example MNL4 is slightly decreased as compared to an on/off ratio of the comparative example MNL3. The on/off ratios of the example MNL3 and the comparative example MNL4 both exceed 10 on average, which are workable in practical applications.

Reference is made to FIG. 17A. For example, the σ/μ value of the V_{RESET} of the comparative example MNL3 is about 6.2%±0.5%, while the σ/μ value of the V_{RESET} of the example MNL4 is about 2.4%±0.5%. For example, the σ/μ value of the V_{SET} of the comparative example MNL3 is about 10.0%±0.5%, while the σ/μ value of the V_{SET} of the example MNL4 is about 6.1%±0.5%. Reference is made to FIG. 17B. For example, the σ/μ value of the resistance of LRS of the comparative example MNL3 is about 16.7%±0.5%, and the σ/μ value of the resistance of LRS of the example MNL4 is about 4.5%±0.5%. For example, the σ/μ value of the resistance of HRS of the comparative example MNL3 is about 27.1%±0.5%, and the σ/μ value of the resistance of HRS of the example MNL4 is about 11.2%±0.5%.

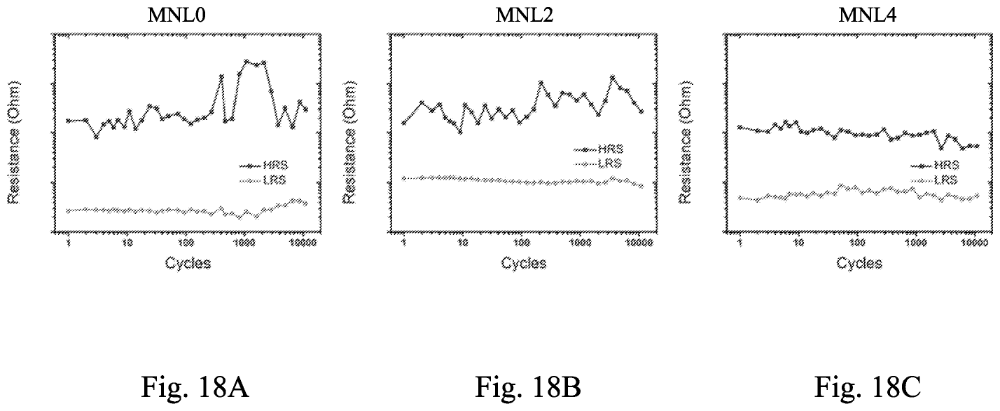

FIGS. 18A-18C are diagrams of resistance versus cycles in accordance with the comparative example MNL0, the example MNL2 and the example MNL4. HRS resistance and LRS resistance of the example MNL2 have a cycle-to-cycle variation smaller than a cycle-to-cycle variation of the comparative example MNL0, which demonstrates an improvement of an RRAM device stability of the example MNL2. The example MNL4 has a small cycle-to-cycle variation of resistance as well.

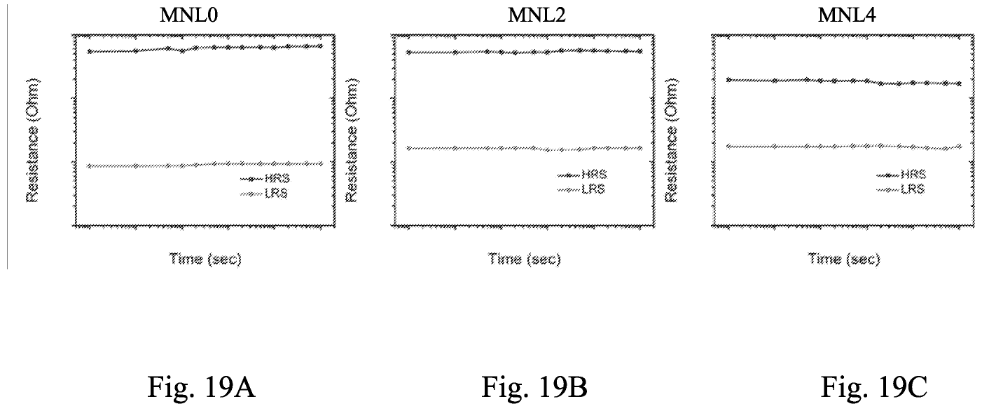

FIGS. 19A-19C are diagrams of resistance versus time in accordance with the comparative example MNL0, the example MNL2 and the example MNL4. Reference is made to FIGS. 19A-19C. The HRS and LRS resistances of the comparative example MNL0, the example MNL2 and the example MNL4 present a high stability over time up to about 10⁶ seconds, indicating the good non-volatility of the RRAM devices based on using the metal nitride layer, such as AlN layer, as switching layers.

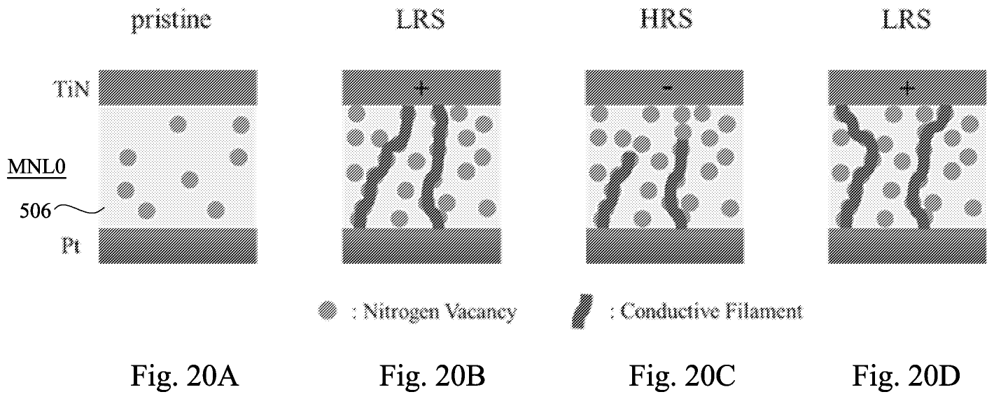

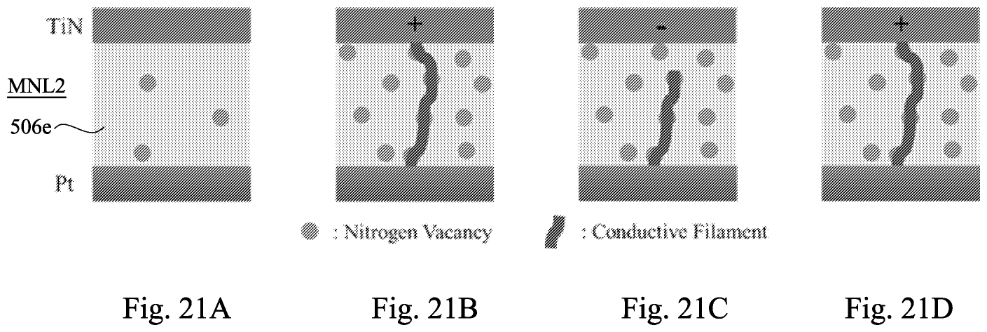

FIGS. 20A-20D are cross-sectional views of a stack of the Pt bottom electrode layer, the metal nitride layer 506 and the TIN top electrode layer in accordance with the comparative example MNL0. For example, the comparative example MNL0 is at a pristine state, a low resistance state (LRS), a high resistance state (HRS) and a subsequent low resistance state (LRS) after the previous HRS shown in FIG. 20A, FIG. 20B, FIG. 20C and FIG. 20D, respectively. FIGS. 21A-21D are cross-sectional views of a stack of the Pt bottom electrode layer, the metal nitride layer 506e and the TIN top electrode layer in accordance with the example MNL2. For example, the example MNL2 is at a pristine state, a low resistance state (LRS), a high resistance state (HRS) and a subsequent low resistance state (LRS) after the previous HRS shown in FIG. 21A, FIG. 21B, FIG. 21C and FIG. 21D, respectively. Because the comparative example MNL0 has an amount of nitrogen vacancies higher than an amount of nitrogen vacancies of the example MNL2, positions of rupture and reconstruction of conductive filaments are not relatively fixed such that the distribution of the V_{RESET}, V_{SET} and HRS resistance are broader than the distribution of V_{RESET}, V_{SET} and HRS resistance of the example MNL2.

Since the comparative example 1 has an amount of nitrogen vacancies greater than an amount of nitrogen vacancies in the example 1, conductive filaments in the comparative example 1 are randomly distributed, resulting in a broad distribution for the LRS resistance thereof. The conductive filaments in the example 1 are fewer than conductive filaments in the comparative example 1, resulting in reduced V_{RESET} and V_{SET} in the example 1.

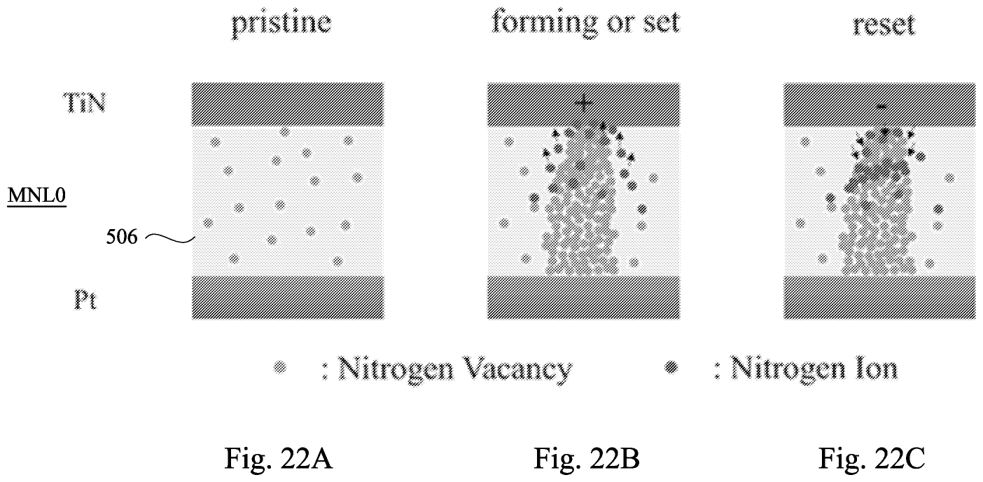

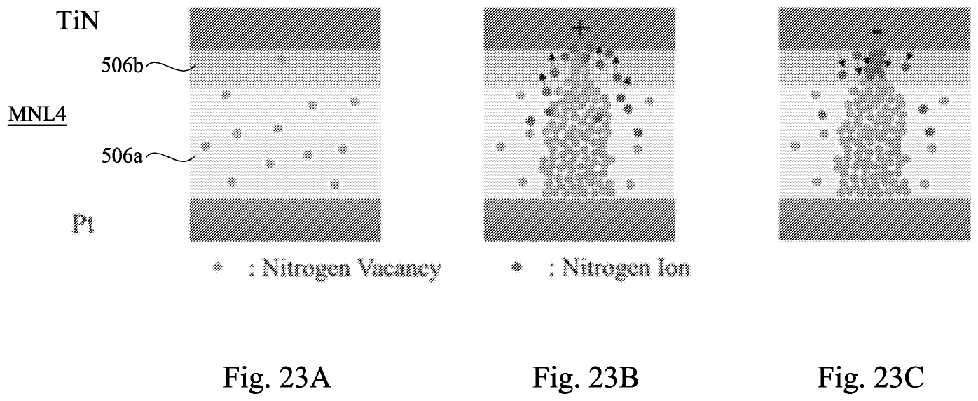

FIGS. 22A-22C are cross-sectional views of a stack of the Pt bottom electrode layer, the metal nitride layer 506 and the TiN top electrode layer in accordance with the comparative example MNL0. For example, the comparative example MNL0 is at a pristine state, at a state after forming or set process, and at a state of reset in FIGS. 22A, 22B and 22C, respectively. FIGS. 23A-23C are cross-sectional views of a stack of the Pt bottom electrode layer, the first metal nitride layer 506a, the second metal nitride layer 506b and the TIN top electrode layer in accordance with the example MNL4. For example, the example MNL4 is at a pristine state, at a state after forming or set process, and at a state of reset in FIGS. 23A, 23B and 23C, respectively. In the example MNL4, the second metal nitride layer 506b (which is treated by the ALA step) is near the TiN top electrode layer and has nitrogen vacancies fewer than nitrogen vacancies of the first metal nitride layer 506a near the Pt bottom electrode layer. Conductive filaments (CFs) in the second metal nitride layer 506b are fewer and have smaller cross-section than those in the first metal nitride layer 506a after the forming or set process. The CFs are more likely to be ruptured in the second metal nitride layer 506b, resulting in the rupture and reconstruction of the CFs being relatively fixed therein. Fewer CFs of the second metal nitride layer 506b near the TiN top electrode layer leads to greater LRS resistance while a gap between the TiN top electrode layer and the broken CFs is relatively small contributes to smaller HRS resistance of the second metal nitride layer 506b.

Referring back to FIG. 16C, by contrast, for the comparative example MNL5, in which the first metal nitride layer 506c (which is treated by the ALA step) is near the Pt bottom electrode layer, a large forming voltage is required to form CFs, and the CFs is relatively large, resulting in a high current in a first few cycles of sweep processes, which leads to an occurrence of hard breakdown.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the atomic layer annealing (ALA) process is the in-situ plasma treatment applied in the plasma-enhanced ALD (PEALD) apparatus without using additional equipment. In other words, the ALA process is compatible with PEALD apparatus without any additional equipment. Another advantage is that by incorporating the ALA step or ALA treatment into an ALD cycle after the purging step or the purging of N₂/H₂ plasma, the energy transfer from the plasma species in the ALA step can enhance the chemical reaction and adatom migration at a film surface, which is favorable for an increase in the film density and a decrease in the nitrogen vacancies. Yet another advantage is that by modulating a frequency of the ALA process incorporated in the ALD cycle, a film quality can be tailored with a monolayer accuracy, which is favorable for RRAM application, and a resistive switching behavior of the RRAM can be affected in various aspects. Yet another advantage is that positions of ALA treatment in the deposition of the metal nitride layer can be modulated such that a position of the rupture and reconstruction of the conductive filaments in the metal nitride layer can be controlled, and a resistive switching behavior of the RRAM can be affected in various aspects. Yet another advantage is that the ALA step in every 2 ALD cycles can contribute to a decrease in operating voltage and uniformity improvement of the resistive switching characteristics. Yet another advantage is that the ALA step near the TiN electrode contributes to a significantly uniformity improvement of the resistive switching characteristics in the RRAM.

In some embodiments, a method includes following steps. A bottom electrode layer is formed over a substrate. A first deposition sequence is performed over the bottom electrode layer. The first deposition sequence comprises pulsing a first precursor over the bottom electrode layer such that the first precursor comprises a first plurality of precursor molecules adsorbing on the bottom electrode layer, performing a first purge after pulsing the first precursor, performing a first plasma treating step using a first treatment gas, wherein the first treatment gas reacts with the first plurality of precursor molecules to form a first monolayer of a film, the film has an Al—N bond with a first intensity, pulsing the first treatment gas, and after pulsing the first treatment gas, performing a second plasma treating step using a second treatment gas such that the film has an Al—N bond with a second intensity. In some embodiments, the method further comprises after performing the first deposition sequence over the bottom electrode layer, performing a second deposition sequence to form a second monolayer of the film, wherein the second deposition sequence is different from the first deposition sequence. In some embodiments, the first intensity of the Al—N bond is different from the second intensity of the Al—N bond. In some embodiments, the first intensity of the Al—N bond is less than the second intensity of the Al—N bond. In some embodiments, the method further comprises forming a top electrode layer over the second monolayer of the film, wherein the top electrode layer is TiN. In some embodiments, the top electrode layer is in contact with the second monolayer of the film. In some embodiments, the bottom electrode layer is Pt. In some embodiments, the film is AlN. In some embodiments, a composition of the first treatment gas is different from a composition of the second treatment gas. In some embodiments, the second treatment gas is a mixture of He and Ar.

In some embodiments, a method comprises the following steps. A bottom electrode layer is formed over a substrate. Alternating stacked first monolayers and second monolayers are formed on the bottom electrode layer, wherein the first monolayers have a material same as a material of the second monolayers, and the first monolayers have a density different from a density of the second monolayers. A top electrode layer is formed over the alternating stacked first monolayers and second monolayers. In some embodiments, the material of the first monolayers and the material of the second monolayers are AlN. In some embodiments, forming the alternating stacked first monolayers and second monolayers comprises repeating a first deposition sequence to form the first monolayers, and repeating a second deposition sequence to form the second monolayers, wherein a number of the first deposition sequence is substantially the same as a number of the second deposition sequence. In some embodiments, the first monolayers have an Al—Al bond with a first intensity different from an Al—Al intensity of the second monolayers. In some embodiments, the first monolayers have an Al—N bond with a first intensity different from an Al—N intensity of the second monolayers. In some embodiments, the top electrode layer and the bottom electrode layer include different materials.

In some embodiments, a memory device comprises a bottom electrode layer over a substrate, a metal nitride layer over the bottom electrode layer, wherein the metal nitride layer includes at least one first monolayer and at least one second monolayer having a density different from a density of the at least one first monolayer, and a top electrode layer over the metal nitride layer. In some embodiments, a number of the at least one first monolayer and a number of the at least one second monolayer are substantially the same. In some embodiments, the at least one first monolayer have an Al—N bond with a first intensity different from an intensity of an Al—N bond of the at least one second monolayer. In some embodiments, the at least one first monolayer have an Al—Al bond with a first intensity different from an intensity of an Al—Al bond of the at least one second monolayer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a bottom electrode layer over a substrate;
performing a first deposition sequence over the bottom electrode layer, wherein the first deposition sequence comprises:
pulsing a first precursor over the bottom electrode layer such that the first precursor comprises a first plurality of precursor molecules adsorbing on the bottom electrode layer;
performing a first purge after pulsing the first precursor;
performing a first plasma treating step using a first treatment gas, wherein the first treatment gas reacts with the first plurality of precursor molecules to form a first monolayer of a film, the film has an Al—N bond with a first intensity;
pulsing the first treatment gas; and
after pulsing the first treatment gas, performing a second plasma treating step using a second treatment gas such that the film has an Al—N bond with a second intensity.

2. The method of claim 1, further comprising:
after performing the first deposition sequence over the bottom electrode layer, performing a second deposition sequence to form a second monolayer of the film, wherein the second deposition sequence is different from the first deposition sequence.

3. The method of claim 2, wherein the first intensity of the Al—N bond is different from the second intensity of the Al—N bond.

4. The method of claim 2, wherein the first intensity of the Al—N bond is less than the second intensity of the Al—N bond.

5. The method of claim 2, further comprising:
forming a top electrode layer over the second monolayer of the film, wherein the top electrode layer is TiN.

6. The method of claim 5, wherein the top electrode layer is in contact with the second monolayer of the film.

7. The method of claim 2, wherein the bottom electrode layer is Pt.

8. The method of claim 1, wherein the film is AlN.

9. The method of claim 1, wherein a composition of the first treatment gas is different from a composition of the second treatment gas.

10. The method of claim 1, wherein the second treatment gas is a mixture of He and Ar.

11. A method, comprising:
forming a bottom electrode layer over a substrate;
forming alternating stacked first monolayers and second monolayers on the bottom electrode layer, wherein the first monolayers have a material same as a material of the second monolayers, and the first monolayers have a density different from a density of the second monolayers; and
forming a top electrode layer over the alternating stacked first monolayers and second monolayers.

12. The method of claim 11, wherein the material of the first monolayers and the material of the second monolayers are AlN.

13. The method of claim 11, wherein forming the alternating stacked first monolayers and second monolayers comprises:
repeating a first deposition sequence to form the first monolayers; and
repeating a second deposition sequence to form the second monolayers, wherein a number of the first deposition sequence is substantially the same as a number of the second deposition sequence.

14. The method of claim 11, wherein the first monolayers have an Al—Al bond with a first intensity different from an Al—Al intensity of the second monolayers.

15. The method of claim 11, wherein the first monolayers have an Al—N bond with a first intensity different from an Al—N intensity of the second monolayers.

16. The method of claim 11, wherein the top electrode layer and the bottom electrode layer include different materials.

17. A memory device, comprising:
a bottom electrode layer over a substrate;
a metal nitride layer over the bottom electrode layer, wherein the metal nitride layer includes at least one first monolayer and at least one second monolayer having a density different from a density of the at least one first monolayer; and
a top electrode layer over the metal nitride layer.

18. The memory device of claim 17, wherein a number of the at least one first monolayer and a number of the at least one second monolayer are substantially the same.

19. The memory device of claim 17, wherein the at least one first monolayer have an Al—N bond with a first intensity different from an intensity of an Al—N bond of the at least one second monolayer.

20. The memory device of claim 17, wherein the at least one first monolayer have an Al—Al bond with a first intensity different from an intensity of an Al—Al bond of the at least one second monolayer.
